(19) United States
(12) Patent Application Publication
(10) Pub. No.: US 2012/0280324 A1
(43) Pub. Date: Nov. 8, 2012

(54) SRAM STRUCTURE AND PROCESS WITH IMPROVED STABILITY

(75) Inventors: Weize Xiong, Plano, TX (US); Gregory Charles Baldwin, Plano, TX (US)

(73) Assignee: TEXAS INSTRUMENTS INCORPORATED, Dallas, TX (US)

(21) Appl. No.: 13/287,737

(22) Filed: Nov. 2, 2011

Related U.S. Application Data
(60) Provisional application No. 61/409,577, filed on Nov. 3, 2010.

(51) Int. Cl. H01L 27/088; H01L 21/336

(52) U.S. Cl. 257/368; 438/585; 438/301; 257/E27.06; 257/E21.409

(57) ABSTRACT

An SRAM memory cell with reduced SiGe formation area using a gate extension (530) that extends over the STI/p-active interface (536). A process for forming an SRAM memory cell with reduced SiGe formation area. A process for forming an SRAM memory cell with improved read/write stability.

### FIELD OF THE INVENTION

This invention relates to the field of integrated circuits. More particularly, this invention relates to improving the stability of an SRAM cell.

### BACKGROUND OF THE INVENTION

The shrinking of MOSFET dimensions for high density, lower power and enhanced performance requires reduced power supply voltages. As a result, dielectric thickness and channel length of the transistors are scaled with power supply voltage. As transistors are scaled, the performance has not improved accordingly. One technique to improve the performance of scaled transistors is to apply stress to the channel region to improve carrier mobility. Compressive stress applied to PMOS transistors improves hole carrier mobility and tensile stress applied to NMOS transistors improves electron carrier mobility. One method of applying compressive stress to PMOS transistors is to remove silicon from the source and drain regions of a PMOS transistor and replace it with silicon germanium (SiGe). Since SiGe has a greater lattice constant than does the silicon substrate, after annealing, it expands and applies a compressive stress to the channel region, significantly improving the drive current of the PMOS transistor.

While the improvement in PMOS drive current is advantageous for PMOS logic transistors, the greater PMOS drive currents for PMOS pull up transistors in the SRAM cell degrades the write margins of the SRAM cell and SRAM cell stability. One possible solution would be to form SiGe stressors for PMOS logic devices but not for the PMOS pull up transistors in the SRAM cell. However, since an SRAM array may occupy the majority of the area in some integrated circuit chips, pattern loading effects and process difficulties in epitaxially growing uniform SiGe may result. Consequently this is not a preferred solution.

Another solution is to form different logic and SRAM PMOS transistors by implanting different extension doses and pocket doses in the SRAM PMOS and the logic PMOS transistors. This solution adds additional patterning and implantation steps increasing cycletime and cost.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

An SRAM memory cell with reduced SiGe formation area due to a gate extension over the STI/active interface. A process for forming an SRAM memory cell with reduced SiGe formation area. A process for forming an SRAM memory cell with improved read/write stability.

### DESCRIPTION OF THE VIEWS OF THE DRAWING

FIG. 1 An example 6-T SRAM memory cell diagram.

FIG. 2 An example 6-T SRAM memory cell layout.

FIG. 3 An example 6-T SRAM memory cell layout formed according to principles of the invention.

FIG. 4A and FIG. 4B are a top down and a cross sectional view of an SRAM cell through PMOS pull up transistors.

FIG. 5A and FIG. 5B are a top down and a cross sectional view of an SRAM cell through PMOS pull up transistors according to principles of the invention.

FIG. 6 is a portion of a process flow for forming an SRAM cell according to principles of the invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

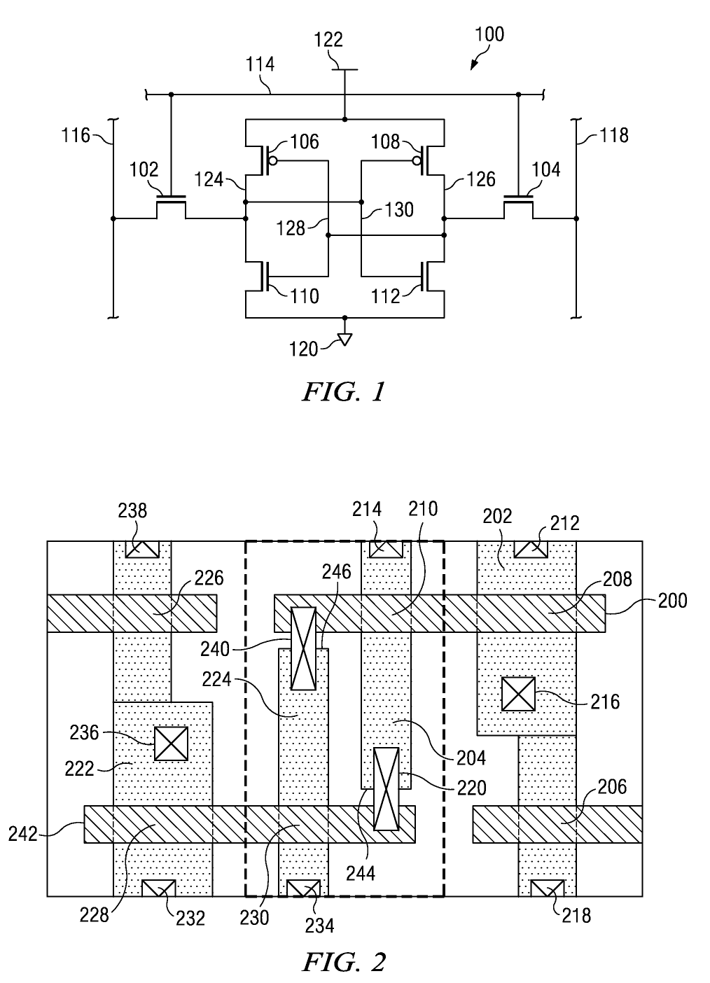

FIG. 1 illustrates and exemplary circuit diagram of a six-transistor SRAM cell, 100, which includes, pass gate transistors, 102 and 104; pull down transistors, 110 and 112; and pull up transistors, 106 and 108. Pull up transistor, 106, and pull down transistor, 110, form a first inverter and pull up transistor, 108, and pull down transistor, 122 form a second inverter. The gate of the first inverter, 128, coupled to the storage node (SNB), 126, of the second inverter and the gate of the second inverter, 130, is coupled to the storage node (SN), 124, of the first inverter. The logic state is stored on storage node (SN), 124, and storage node bar (SNB) as a high and a low voltage. For example, a logic state “1” may be stored as a high voltage on SN, 124, with pull up transistor, 106, turned on and pull down transistor, 110, off and with a low voltage on SNB, 126, with pull up transistor, 108, off and pull down transistor, 112, on. Wordline (WL), 114, turns on the pass gate transistors, 102 and 104, connecting them to bitline (BL), 116, and bitline bar (BLB), 118, during a read or write operation.

During a read operation, BL, 116, and BLB, 118, may be precharged high before the wordline, 114, turns on pass gate transistors, 102 and 104. If the above described logic state “1” is stored in the SRAM cell, pull down transistor, 110, is off and pull down transistor, 112, is on. This causes BLB, 118, to discharge and BL, 116 to not discharge. A differential sense amplifier then reads the differential voltage on the bitlines as a logic state “1”.

To write a logic state “0” into an SRAM cell that contains the logic state “1” described above, BL, 116, may be precharged to ground and BLB, 118 may be precharged to a high voltage before WL, 114, turns pass gate transistors, 102 and 104, on. With pass gate, 102, on, SN, 124, discharges to BL, 126, and with pass gate, 104, on, SNB 126, is charged by BLB, 118, until the trip voltage of the SRAM cell is reached. At the trip point, pull up transistor, 106, turns off, pull down transistor, 110, turns on, pull up transistor, 108, turns on, and pull down transistor, 112, turns off. A low voltage is now on SN, 124, and a high voltage on SNB, 126, so a logic state “0” is now written into the SRAM memory cell.

The relative strengths of especially the pull up transistor to the pass gate transistor may determine the SRAM cell read and write stability. For example, a strong pull up transistor relative to the pass gate facilitates SRAM write but degrades SRAM read whereas a weak pull up transistor relative to the pass gate facilitates SRAM read but degrades SRAM write. It is desirable to balance the relative strengths of the pull up and pass gate transistors to balance SRAM read and write stability. SiGe on the SRAM PMOS typically strengthens the pull up transistor relative to the pass gate transistor causing the SRAM cell read-write stability to become unbalanced.

An example layout of a 6-T SRAM cell is shown in FIG. 2. NMOS pass transistor gate, 206, and NMOS pull down transistor gate, 208, are formed over n-active, 202, and PMOS pull up transistor gate, 210, is formed over p-active, 204. NMOS pull down transistor 208 and PMOS pull up transistor 210 form a first inverter 200 in the SRAM cell. Vdd (array voltage) is connected to p-active, 204, through contact, 214, and Vss (ground) is connected to n-active, 202, through contact, 212. A first bitline is connected to the first inverter through contact 218. Contact 216 is shorted to elongated contact 220 with metal (not shown) to form a first SRAM storage node.

NMOS pass transistor gate, 226, and NMOS pull down transistor gate, 228, are formed over n-active, 222, and PMOS pull up transistor gate, 230, is formed over p-active, 224. NMOS pull down transistor 228 and PMOS pull up transistor 230 form a second inverter 242 in the SRAM cell. Vdd (array voltage) is connected to p-active, 224, through contact, 234, and Vss (ground) is connected to n-active, 222, through contact, 232. A second bitline, usually called bitline bar, is connected to the second inverter through contact 238. Contact 236 is shorted to elongated contact 240 with metal (not shown) to form a second SRAM storage node.

Elongated contact 220 shorts (cross couples) the first storage node to the gate 242 of the second inverter and elongated contact 240 shorts (cross couples) the second storage node to the gate 200 of the second inverter.

To enhance the performance of the PMOS transistors, 210 and 230, single crystal silicon in p-active areas such as, 204 and 224, that are adjacent to the PMOS transistor gates, 210 and 230, is etched to form a trench which is then refilled with epitaxially grown SiGe. Since the lattice constant of SiGe is larger than single crystal silicon, compressive stress is applied to the channel region of the PMOS transistors, 210 and 230 enhancing transistor performance. The stress enhancement may improve the performance of the PMOS pull up transistors, 210 and 230, relative to the NMOS pass gate transistors, 206 and 226, causing an unbalance in the read/write stability of the SRAM cell. It may be desirable to reduce the stress enhancement to better match SRAM read and write stability.

In the SRAM cell in FIG. 2 the STI/p-type active interface area 244 and 246 is exposed to the contact etch during the formation of the elongated contacts, 220 and 240. The contact etch may damage this area causing increased diode leakage.

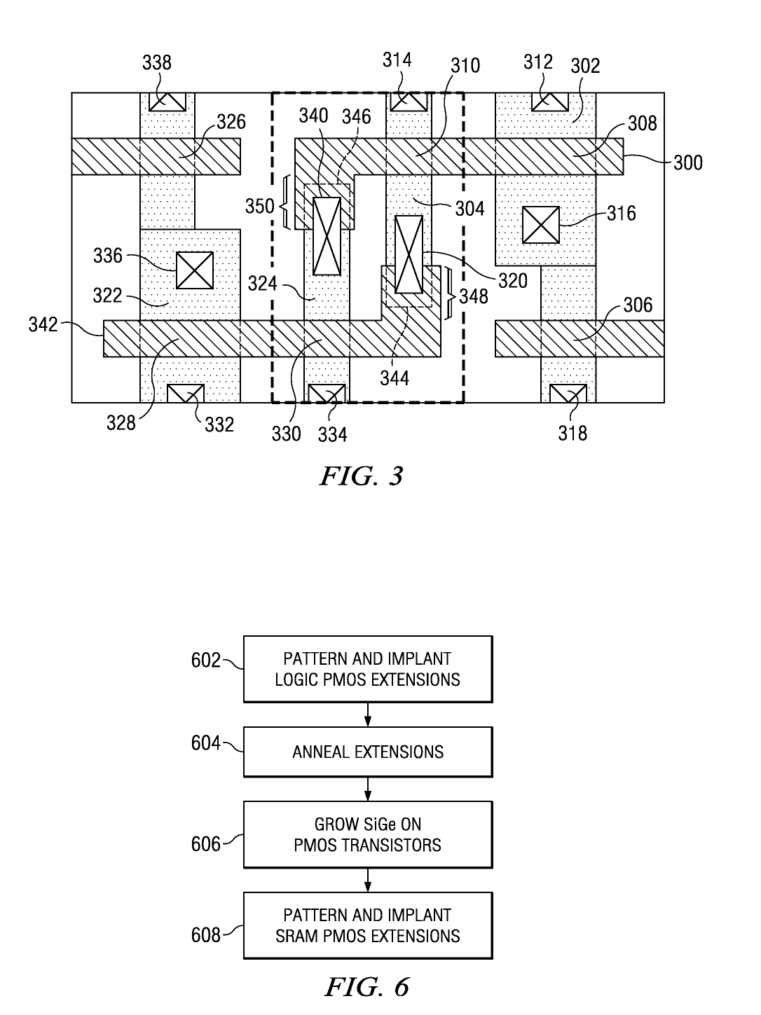

An example embodiment illustrating a method of improving SRAM read/write stability without adding processing cost or 6-T SRAM cell area is shown in FIG. 3. NMOS pass transistor gate, 306, and NMOS pull down transistor gate, 308, are formed over n-active, 302, and PMOS pull up transistor gate, 310, is formed over p-active, 304. NMOS pull down transistor 308 and PMOS pull up transistor 310 form a first inverter 300 in the SRAM cell. Vdd (array voltage) is connected to p-active, 304, through contact, 314, and Vss (ground) is connected to n-active, 302, through contact, 312. A first bitline is connected to the first inverter through contact 318. Contact 316 is shorted to elongated contact 320 with metal (not shown) to form a first SRAM storage node.

NMOS pass transistor gate, 326, and NMOS pull down transistor gate, 328, are formed over n-active, 322, and PMOS pull up transistor gate, 330, is formed over p-active, 324. NMOS pull down transistor 328 and PMOS pull up transistor 330 form a second inverter 342 in the SRAM cell. Vdd (array voltage) is connected to p-active, 324, through contact, 334, and Vss (ground) is connected to n-active, 322, through contact, 332. A second bitline, usually called bitline bar, is connected to the second inverter through contact 338. Contact 336 is shorted to elongated contact 340 with metal (not shown) to form a second SRAM storage node.

Elongated contact 320 shorts (cross couples) the first storage node to the gate 342 of the second inverter and elongated contact 340 shorts (cross couples) the second storage node to the gate 300 of the second inverter.

In this embodiment SRAM cell, extension, 348 is added to the inverter gate, 330, to partially cover p-active area, 304, blocking SiGe formation from a portion of the p-active area. In this embodiment, SiGe is formed in the p-type active area 304 between the extension 342 and the gate of the PMOS transistor 310. The gate extension 342 is formed by changing the gate photoresist pattern so no additional processing cost is incurred. A similar extension 350 is added to gate 310 over p-active 324. It should be noted that gate extensions, like 348 and 350 may be added to the SRAM PMOS transistors without adding such extensions to PMOS transistors outside the SRAM cells such as PMOS transistors in a logic area. Reduction of the SiGe areas 304 and 324 reduces the stress enhancement applied to the transistor channel under the PMOS transistor gates, 310 and 330. Reducing the performance of the PMOS pull up transistors 310 and 330 relative to the NMOS pass gate transistors, 306 and 326, may improve the write stability of the 6-T SRAM cell. In a preferred embodiment the smallest dimension in which SiGe may be formed in the p-active areas, 304 and 324, between PMOS gate extensions, 342 and 344, and PMOS pull up transistor gates, 310 and 330, is about 30 nm. Another advantage of adding gate extensions, 348 and 350, is that it covers the shallow trench isolation (STI)/p-active edges, 344 and 346, where SiGe defects typically may form and causing increased diode leakage. Yet another advantage is that the gate extensions, 348 and 350, covers the STI/substrate edges, 344 and 346, protecting this area from the contact etch during formation of the elongated contacts, 320 and 340. Protecting the STI/substrate interfaces, 344 and 346, from etch damage may avoid additional diode leakage. In an example embodiment the width of the gate extension is larger than the gate length of the PMOS transistor in the SRAM cell to which the gate extension is attached.

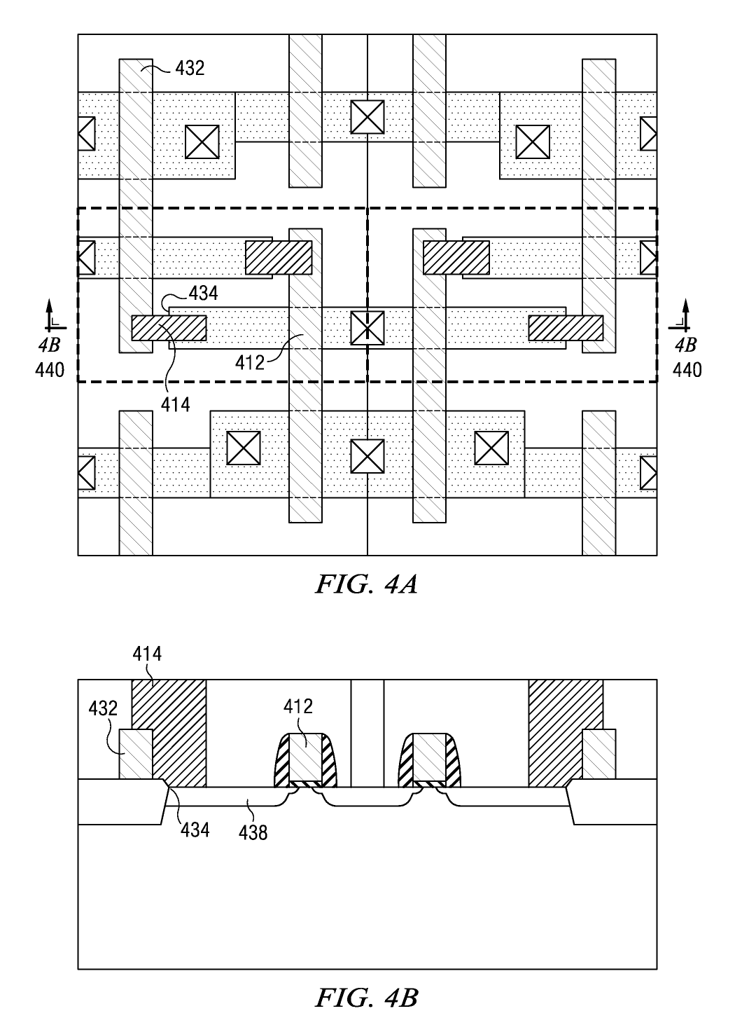

The cross section in FIG. 4B is taken along the dashed line 440 through PMOS transistor 412 in FIG. 4A. As shown in FIG. 4B, the edge of the SiGe source and drain diffusion 438 abuts the STI 434. The SiGe/STI interface is frequently a region with high defects resulting in increased diode leakage. In addition, the SiGe/STI interface region 434 is exposed to the elongated contact 414 etch which may additionally damage this area increasing diode leakage. The elongated contact 414 electrically connects inverter gate 432 to the source and drain diffusion 438 on the PMOS transistor 412.

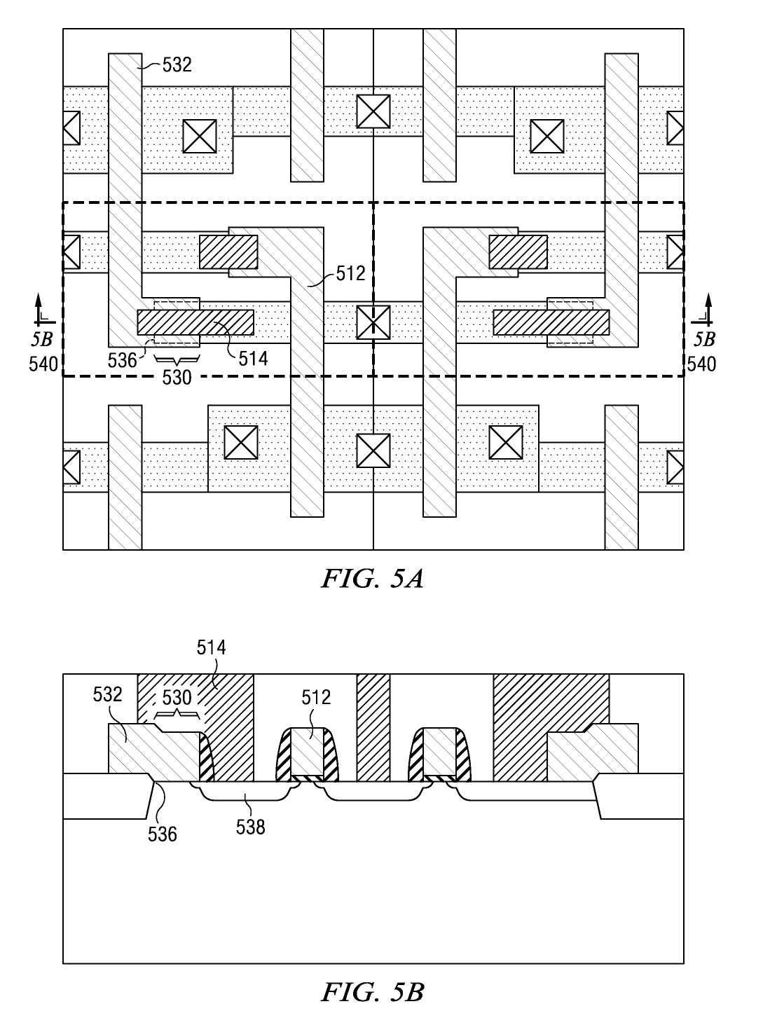

The cross section in FIG. 5B is taken along the dashed line 540 through PMOS transistor 512 in FIG. 5A. As shown in FIG. 5B, the edge of the SiGe source and drain diffusion 538 is self aligned to the edge of the gate extension 530. The gate extension covers the STI/substrate interface 536 and prevents SiGe from coming into contact with STI. The SiGe/STI interface is frequently a region with high defects resulting in increased diode leakage. This embodiment may improve diode leakage by preventing formation of a SiGe/STI interface. In addition, the STI/substrate interface region 534 is protected during the elongated contact 514 etch. This prevents damage to this area thereby avoiding damage to this area and an increase in diode leakage. The elongated contact 514 electrically connects inverter gate 532 to the source and drain diffusion 538 on the PMOS transistor 512.

In typical CMOS process flows which employ SiGe stress enhancement, the SiGe is formed either before extension plus halo implant and anneal or after extension plus halo implant and anneal for the source and drain extension plus halo implants for both logic and SRAM transistors. The advantage of forming SiGe after the extensions are formed is improved stress enhancement. The extension and halo implants into SiGe may partially amorphize the SiGe resulting in partial stress relaxation. In addition the high temperature dopant activation anneal may also cause partial stress relaxation. Consequently, SiGe is typically formed after extension plus halo implant and anneal in high performance manufacturing flows. Unfortunately the increased stress has the disadvantage of additionally unbalancing the SRAM read/write stability. In process flows where the SiGe is formed prior to the logic and SRAM extension implants, stress is partially relaxed due to the partial amorphization. Unfortunately the reduced stress has the disadvantage of reducing logic transistor performance.

An embodiment process flow which improves SRAM read/write stability in a high performance CMOS manufacturing flow is illustrated in FIG. 6. In this manufacturing flow, the source and drain extension plus halo for the logic transistors are implanted and annealed, steps 602 and 604 in FIG. 6, prior to growing the SiGe, step 606, whereas the source and drain extension plus halo for the SRAM transistors, step 608, implantation and anneal is performed after SiGe formation. Anneal of the logic transistor source and drain extensions and halos prior to SiGe formation is optional. Since the source and drain extensions and halo for the logic transistors are formed prior to the SiGe growth, SiGe stress is not partially relaxed as a result of implantation damage in the logic areas so maximum stress is applied to the logic PMOS transistors producing maximum performance boost. However, since the SiGe is already in place when the SRAM transistor source and drain extensions plus halos are implanted, the SRAM SiGe will see partial stress relaxation due to implantation damage. This partial stress relaxation reduces the strength of the SRAM PMOS pull down transistors relative to the SRAM NMOS pass gate transistor resulting in improved SRAM read/write stability. This embodiment provides maximum stress enhancement to the core logic PMOS transistors and reduced stress enhancement to SRAM PMOS transistors. The reduced stress enhancement of the SRAM PMOS transistors improves SRAM read/write stability by reducing the strength of the SRAM PMOS pull up transistor relative to the SRAM NMOS pull down transistor

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. An integrated circuit, comprising:
an SRAM memory cell, said SRAM memory cell further including:
a first PMOS pull up transistor in a first p-type active region with a first gate extension which overlies a portion of a second p-type active region;
a second PMOS pull up transistor in said second p-type active region with a second gate extension that overlies a portion of said first p-type active region; and where SiGe is formed in a portion of said first p-type active region which lies between a gate of said first PMOS pull up transistor and said second gate extension and where SiGe is formed in a portion of said second p-type active region which lies between a gate of said second PMOS pull up transistor and said first gate extension.

2. The integrated circuit of claim 1 where a first distance between said gate of said first PMOS pull up transistor and said second gate extension in said first p-type active region is at least 30 nm and where a second distance between said gate of said second PMOS pull up transistor and said first gate extension in said second p-type active region is at least 30 nm.

3. The integrated circuit of claim 1 where a first width of said first gate extension is larger than a gate length of said gate of said first PMOS pull up transistor and where a second width of said second gate extension is larger than a gate length of said gate of said second PMOS pull up transistor.

4. The integrated circuit of claim 1 where said first gate extension overlies an interface between STI and said second p-type active region and where said second gate extension overlies an interface between STI and said first p-type active region.

5. The integrated circuit of claim 1 where a first elongated contact shorts said first gate extension to said second p-type active area and where a second elongated contact shorts said second gate extension to said first p-type active area.

6. A method of forming an integrated circuit, comprising the steps:
forming a first p-active area and a second p-active area in an SRAM cell;
forming a gate of a first PMOS pull up transistor in said first p-active area and a gate of a second PMOS pull up transistor in said second p-active area;
forming a first gate extension on said gate of said first PMOS pull up transistor and a second gate extension on said gate of said second PMOS pull up transistor where said first gate extension overlies a portion of said second p-active area and where said second gate extension overlies a portion of said first p-active area;
forming SiGe in said first p-type active area which lies between said gate of said first PMOS pull up transistor gate and said second gate extension; and
forming SiGe in said second p-active area which lies between said gate of said second PMOS pull up transistor and said first gate extension.

7. The method of claim 6 where a first distance between said gate of said first PMOS pull up transistor and said second gate extension in said first p-active area is at least 30 nm and where a second distance between said gate of second PMOS pull up transistor and said first gate extension in said second p-moat area is at least 30 nm

8. The method of claim 6 where a first width of said first gate extension is larger than a gate length of said gate of said first PMOS pull up transistor and where a second width of said second gate extension is larger than a gate length of said gate of said second PMOS pull up transistor.

9. A method of forming an integrated circuit, comprising the steps:
implanting first source and drain extensions and first source and drain halos self aligned to gates of logic PMOS transistors;
forming SiGe in p-type active regions adjacent to said gates of said logic PMOS transistors and in p-type active regions adjacent to gates of SRAM PMOS transistors; and
implanting second source and drain extensions and second source and drain halos self aligned to said gates on said SRAM PMOS transistors after said step of forming SiGe.

10. The method of claim 9 further comprising annealing said first source and drain extensions and said first source and drain halos prior to said step of forming SiGe.
